(19) United States
(12) Patent Application Publication
(10) Pub. No.: US 2013/0049198 A1
(43) Pub. Date: Feb. 28, 2013

(54) SEMICONDUCTOR PACKAGE STRUCTURE AND MANUFACTURING METHOD THEREOF

(71) Applicants: Tsung-Jen Liao, Hsinchu (TW); Cheng-Tang Huang, Hsinchu (TW); Mei-Fang Peng, Hsinchu (TW)

(72) Inventors: Tsung-Jen Liao, Hsinchu (TW); Cheng-Tang Huang, Hsinchu (TW); Mei-Fang Peng, Hsinchu (TW)

(73) Assignee: CHIPMOS TECHNOLOGIES INC., Hsinchu (TW)

(21) Appl. No.: 13/366,367

(22) Filed: Feb. 6, 2012

(30) Foreign Application Priority Data
Aug. 25, 2011 (TW) 100130539

(51) Int. Cl. H01L 23/48; H01L 21/78

(52) U.S. Cl. 257/738; 438/460; 257/E23.023; 257/E21.599

(57) ABSTRACT

A method of manufacturing a semiconductor package structure is provided. A chip is provided. An active surface of the chip is disposed on a carrier. A molding compound is formed on the carrier with a metal layer disposed thereon. The metal layer has an upper and lower surface, multiple cavities formed on the upper surface and multiple protrusions formed on the lower surface and corresponding to the cavities. The protrusions are embedded in the molding compound. The metal layer is patterned to form multiple pads on a portion of the molding compound. The carrier and the molding compound are separated. Multiple through holes are formed on the molding compound exposing the protrusions. A redistribution layer is formed on the molding compound and the active surface of the chip. Multiple solder balls are formed on the redistribution layer. A portion of the solder balls are correspondingly disposed to the pads.

### CROSS-REFERENCE TO RELATED APPLICATION

This application claims the priority benefit of Taiwan application serial no. 100130539, filed on Aug. 25, 2011. The entirety of the above-mentioned patent application is hereby incorporated by reference herein and made a part of this specification.

### BACKGROUND OF THE INVENTION

1. Field of the Invention

The invention relates to a semiconductor device and a manufacturing method thereof. More particularly, the invention relates to a semiconductor package structure and a manufacturing method thereof.

2. Description of Related Art

A chip package is used to protect exposed chips, lower the contact density of chips, and provide chips with good heat dissipation. When the contact density of a chip continuously increases and the area of the chip becomes smaller and smaller, it is difficult for the contact points of the chip to be re-distributed on the surface of the chip as a surface matrix. Even if the surface of the chip can accommodate all the contact points, the distance between each contact point will be too small, affecting the electrical reliability in the subsequent soldering of the solder balls.

Thus, in conventional technology, a molding compound can first be used to package the chip to increase the area of the chip, wherein an active surface of the chip and the bottom surface of the molding compound is exposed. Then, a redistribution layer is formed on the active surface of the chip and the bottom surface of the molding compound, and solder balls are respectively formed on the contact points of the redistribution layer, to act as a medium for an electrical connection between the chip and an external contact point. That is to say, the active surface of the chip and the solder balls are located on the same plane. Since mold flash is generated during packaging, this causes the molding compound to extend to a part of the active surface of the chip, which pollutes the active surface of the chip. Thus, this method is unable to be applied to CMOS chips.

Furthermore, the aforementioned method is unable to use a vertical stacking method to package multiple semiconductor components (such as chips) to the same package structure. Conventional methods use a design of molding compounds packaging chips to increase the area of a chip. However, since the redistribution layer is located on the active surface of the chip and the bottom surface of the molding compound, a stacking formation can not be used to stack the chips. Therefore, how to effectively reduce the thickness and dimensions of a package structure for multiple stacked chips, while considering the electrical reliability of the package structure, is a topic to be urgently resolved.

### SUMMARY OF THE INVENTION

The invention provides a semiconductor package structure and a manufacturing method thereof. The invention has the advantages of low cost, simplicity in manufacturing, and adaptability for mass production.

The invention further provides a method of manufacturing a semiconductor package structure. The method includes the following steps. A chip is provided, wherein the chip includes an active surface and a back surface opposite to each other. The chip is disposed on a carrier, wherein the active surface faces the carrier. A first molding compound is formed on the carrier to cover the chip. A metal layer is disposed on the first molding compound. The metal layer includes an upper surface and a lower surface opposite to each other, a plurality of cavities formed on the upper surface and a plurality of protrusions formed on the lower surface and the corresponding to the cavities, wherein the protrusions are embedded into the first molding compound. The metal layer is patterned so as to form a plurality of pads on a portion of the first molding compound, wherein each of the cavities are respectively located on a top surface of each of the pads, and each of the protrusions are respectively located on a bottom surface of each of the pads. The carrier and the first molding compound are separated from each other. A plurality of through holes is formed on the first molding compound so as to expose the protrusions. A redistribution layer is formed on the first molding compound and the active surface of the chip, wherein a portion of the redistribution layer extends from the first molding compound to the active surface of the chip and the through holes, so that the chip is electrically connected to the pads through the portion of the redistribution layer. A plurality of first solder balls are formed on the redistribution layer, wherein a portion of the first solder balls are correspondingly disposed to the pads.

In an embodiment of the invention, the method of forming the cavities and protrusions includes: providing a metal material layer; forming a first patterned photoresist layer on a first surface of the metal material layer; removing a portion of the metal material layer by using the first patterned photoresist layer as a mask to form cavities on the first surface of the metal material layer; forming a second patterned photoresist layer on a second surface of the metal material layer; and removing a portion of the metal material layer by using the second patterned photoresist layer as a mask, to form protrusions on the second surface of the metal material layer.

In an embodiment of the invention, the method of patterning the metal layer includes: forming a third patterned photoresist layer on the upper surface of the metal layer; and removing a portion of the metal layer by using the third photoresist layer as a mask until a portion of the first molding compound is exposed.

In an embodiment of the invention, the method of manufacturing the semiconductor package structure further includes: forming a second solder ball on the top surface of each pad.

In an embodiment of the invention, the method of manufacturing the semiconductor package structure further includes: forming a second molding compound on the first molding compound, wherein the second molding compound covers the pads and the first molding compound.

In an embodiment of the invention, the method of manufacturing the semiconductor package structure further includes: performing a singulation process after forming the first solder balls so as to form multiple independent package units.

In an embodiment of the invention, the method of manufacturing the semiconductor package structure further includes: disposing the metal layer on the first molding compound when the first molding compound is in a half-cured state, so that the protrusions are embedded into the first molding compound; and performing a baking step towards the first molding compound and the metal layer before patterning the metal layer so as to cure the first molding compound.

The invention provides a semiconductor package structure, including a chip, a first molding compound, a metal layer, a redistribution layer and a plurality of first solder balls. The chip has an active surface and a back surface opposite to each other. The first molding compound covers the chip and has a plurality of through holes, wherein a bottom surface of the first molding compound and the active surface of the chip are substantially coplanar. The metal layer is disposed on a portion of the first molding compound, and includes a plurality of cavities, a plurality of protrusions corresponding to the cavities, and a plurality of pads. Each of the cavities are respectively located on a top surface of each of the pads, and each of the protrusions are respectively located on a bottom surface of each of the pads. The through holes expose the protrusions. A redistribution layer is disposed on the first molding compound and the active surface of the chip, wherein a portion of the redistribution layer extends from the first molding compound to the active surface of the chip and the through holes, so that the chip is electrically connected to the pads through the portion of the redistribution layer. A plurality of first solder balls is disposed on the redistribution layer, wherein a portion of the first solder balls are correspondingly disposed to the pads.

In an embodiment of the invention, the semiconductor package structure further includes a plurality of second solder balls, disposed on the top surface of the pads.

In an embodiment of the invention, the semiconductor package structure further includes, a second molding compound disposed on the first molding compound, wherein the second molding compound covers the pads and the first molding compound.

Based on the above, in the invention, since the metal layer that was formed beforehand is disposed on the first molding compound, thus the semiconductor package structure of the invention has a better heat dissipation effect, and the entire semiconductor structure reliability is increased through the metal layer, to prevent the entire structure from warpage effects. Furthermore, since the method of manufacturing the metal layer has the advantages of simplicity and adaptability for mass production, thus the semiconductor package structure of the invention that adopts the metal layer also effectively reduces production cost.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1A to FIG. 1G are schematic cross-sectional views of a method of manufacturing a semiconductor package structure according to an embodiment of the invention.

FIG. 1H is a schematic cross-sectional view of a semiconductor package structure according to an embodiment of the invention.

FIG. 2 is a schematic cross-sectional view of multiple stacked semiconductor package structures according to an embodiment of the invention.

### DESCRIPTION OF EMBODIMENTS

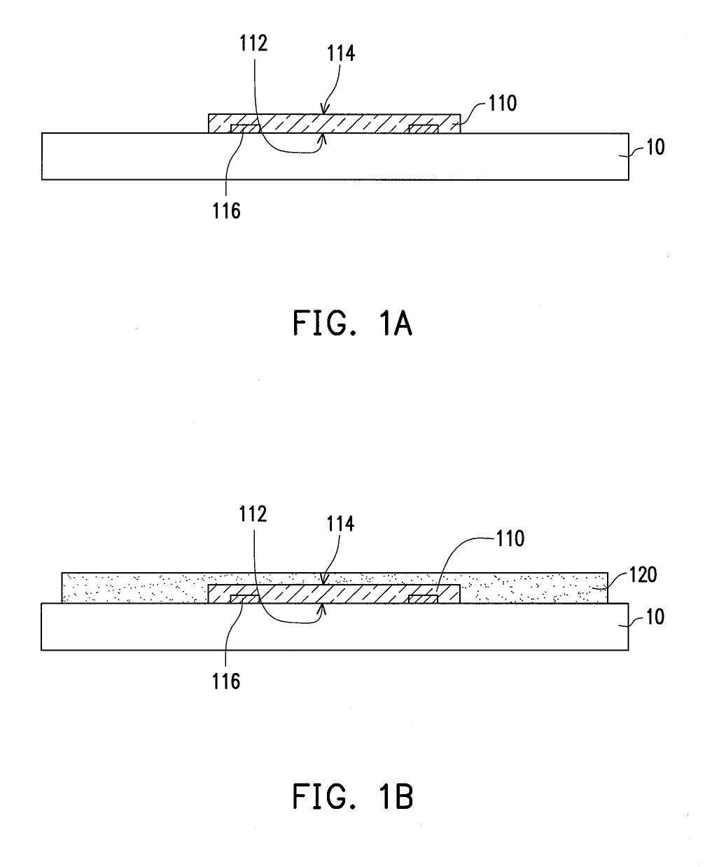

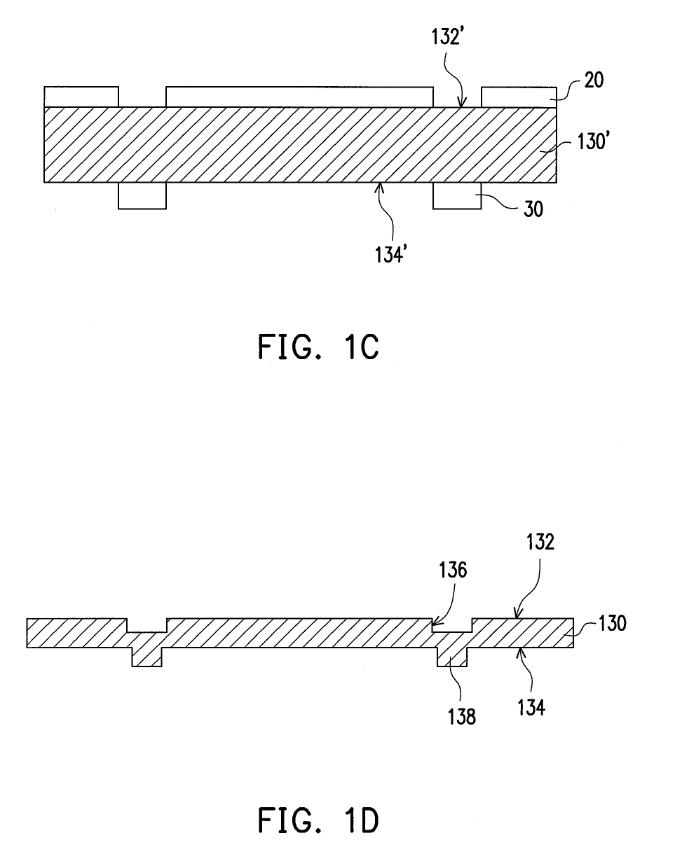

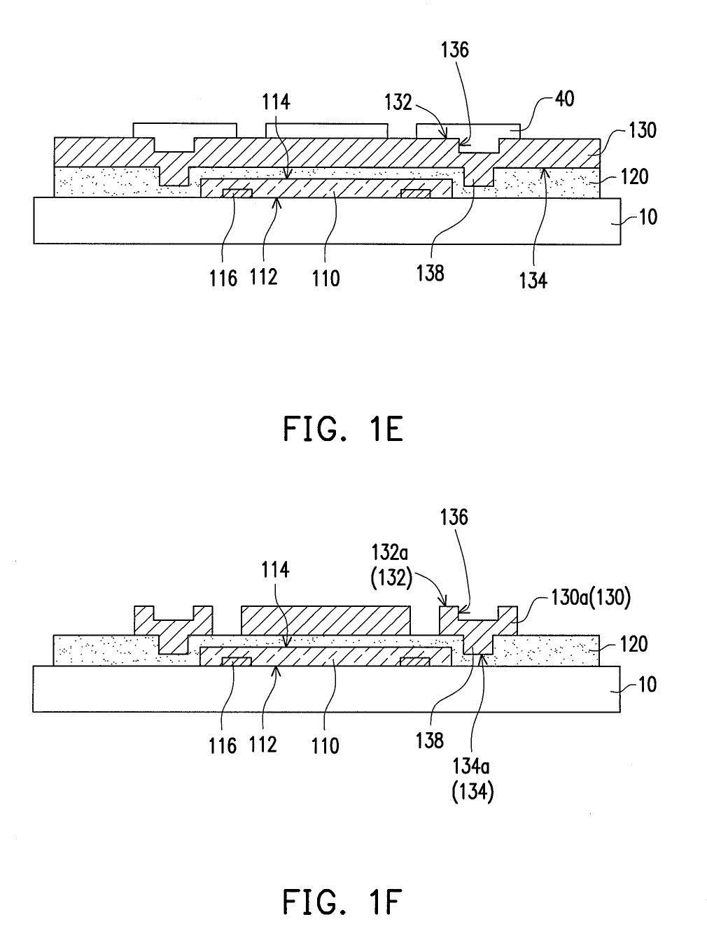

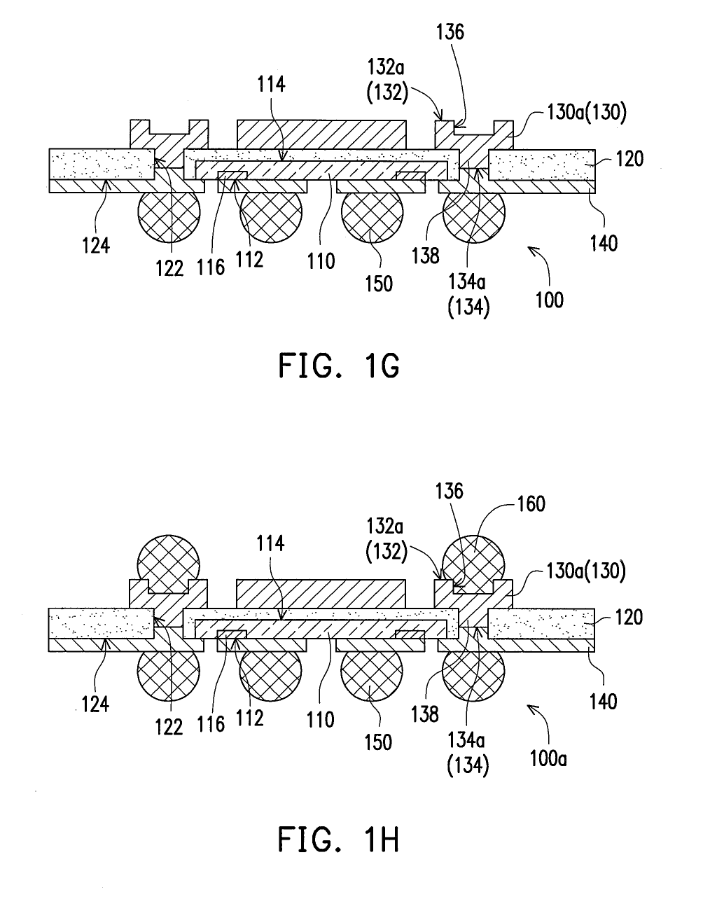

FIG. 1A to FIG. 1G are schematic cross-sectional views of a method of manufacturing a semiconductor package structure according to an embodiment of the invention. Referring to FIG. 1A, the method of manufacturing a semiconductor package structure of the embodiment includes the following steps. First, a chip 110 is provided, wherein the chip 110 includes an active surface 112 and a back surface 114 opposite to each other, and a plurality of solder pads 116 located on the active surface 112. Next, the chip 110 is disposed on a carrier 10, wherein the active surface 112 of the chip 110 faces the carrier 10.

Next, referring to FIG. 1B, a first molding compound 120 is formed on the carrier 10, to cover the chip 110 and a portion of the carrier 10.

After that, referring to FIG. 1C and FIG. 1D, a metal material layer 130′ is provided. A photoresist layer (not shown) is entirely coated on a first surface 132′ and a second surface 134′ of the metal material layer 130′. Then, a first patterned photoresist layer 20 exposes a portion of the first surface 132′, and a second patterned photoresist layer 30 exposes a portion of the second surface 134′ through an exposure and development processes. Subsequently, a portion of the metal material layer 130′ is removed by using the first patterned photoresist layer 20 as a mask so as to form a plurality of cavities 136 on the first surface 132′ of the metal material layer 130′. Then, a portion of the metal material layer 130′ is removed by using the second patterned photoresist layer 30 acting as a mask so as to form a plurality of protrusions 138 on the second surface 134′ of the metal material layer 130′. Next, the first patterned photoresist layer 20 and the second patterned photo resist layer 30 are removed, to complete the manufacture of a metal layer 130. Simply put, the metal layer 130 of the embodiment includes an upper surface 132 and a lower surface 134 opposite to each other, a plurality of cavities 136 formed on the upper surface 132 and a plurality of protrusions 138 formed on the lower surface 134 and corresponding to the cavities 136.

Next, referring to FIG. 1E, the metal layer 130 is disposed on the first molding compound 120, wherein the protrusions 138 of the metal layer 130 are embedded into the first molding compound 120. It should be noted that the metal layer 130 is disposed on the first molding compound 120 when the first molding compound 120 of the embodiment is in a half-cured state. This way, the protrusions 138 can be easily embedded into the first molding compound 120. Next, a baking step is performed towards the first molding compound 120 and the metal layer 130 so as to cure the half-cured first molding compound 120. A third patterned photoresist layer 40 is formed on the upper surface 132 of the metal layer 130, to pattern the metal layer 130. Herein, the third patterned photoresist layer 40 exposes a portion of the upper surface 132.

Next, referring to both FIG. 1E and FIG. 1F, a portion of the metal layer 130 is removed by using the third photoresist layer 40 as a mask until a portion of the first molding compound 120 is exposed, and a plurality of pads 130a are formed on a partial region of the first molding compound 120. Each of the cavities 136 are respectively located on a top surface 132a of each of the pads 130a, and each of the protrusions 138 are respectively located on a bottom surface 134a of each of the pads 130a.

Referring to FIG. 1G, the carrier 10 and the first molding compound 120 are separated from each other. A plurality of through holes 122 is formed on the first molding compound 120 so as to expose the protrusions 138. The method of forming the through holes 122 is with, for example, laser ablating, to remove portions of the first molding compound 120. Next, a redistribution layer 140 is formed on the first molding compound 120 and the active surface 112 of the chip 110, wherein a portion of the redistribution layer 140 extends from the first molding compound 120 to the active surface 112 of the chip 110 and the through holes 122, so that the solder pads 116 of the chip 110 is electrically connected to the pads 130a through the portion of the redistribution layer 140. Finally, a plurality of first solder balls 150 are formed on the redistribution layer 140, wherein a portion of the first solder balls 150 are correspondingly disposed to the pads 130a. Thereby, the semiconductor package structure 100 is completely formed.

Structurally, please refer to FIG. 1G The invention provides the semiconductor package structure 100 including the chip 110, the first molding compound 120, the metal layer 130, the redistribution layer 140, and the first solder balls 150. The chip 110 includes an active surface 112 and a back surface 114 opposite to each other. The first molding compound 120 covers the chip 110 and includes a plurality of through holes 122, wherein a bottom surface 124 of the first molding compound 120 and the active surface 112 of the chip 110 are substantially coplanar. The metal layer 130 is disposed on a portion of the first molding compound 120, and includes a plurality of cavities 136, a plurality of protrusions 138 corresponding to the cavities 136, and a plurality of pads 130a. Each of the cavities 136 are respectively located on a top surface 132a of each of the pads 130a, and each of the protrusions 138 are respectively located on a bottom surface 134a of each of the pads 130a. The through holes 122 expose the protrusions 138. The redistribution layer 140 is disposed on the first molding compound 120 and the active surface 112 of the chip 110, wherein a portion of the redistribution layer 140 extends from the first molding compound 120 to the active surface 112 of the chip 110 and the through holes 122, so that the solder pads 116 of the chip 110 are electrically connected to the pads 130a through the portion of the redistribution layer 140. The first solder balls 150 are disposed on the redistribution layer 140, wherein a portion of the first solder balls 150 are correspondingly disposed to the pads 130a.

FIG. 1H is a schematic cross-sectional view of a semiconductor package structure according to an embodiment of the invention. Referring to FIG. 1H, the semiconductor package structure 100a of the embodiment is similar to the semiconductor package structure 100 of FIG. 1G The difference is, the semiconductor package structure 100a of the embodiment further includes a plurality of second solder balls 160 formed on the top surface 132a of each of the pads 130a, wherein the second solder balls 160 are embedded into the cavities 136, and are correspondingly disposed to the first solder balls 150.

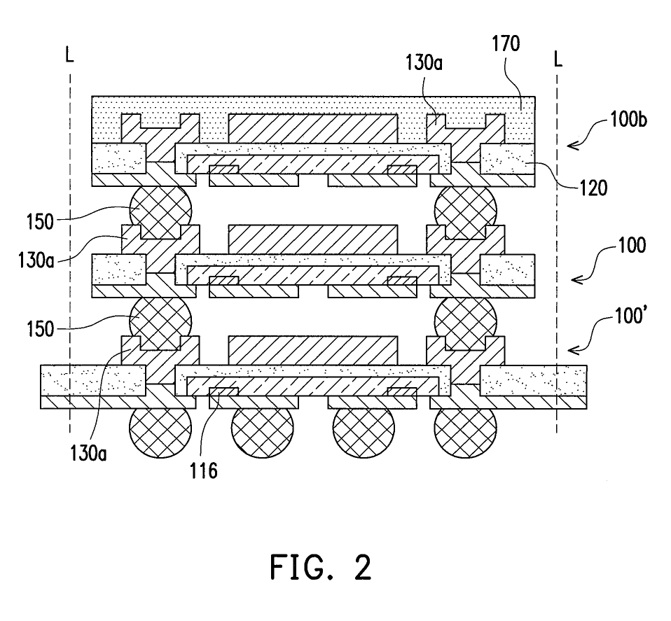

FIG. 2 is a schematic cross-sectional view of multiple stacked semiconductor package structures according to an embodiment of the invention. Referring to FIG. 2, the embodiment vertically stacks multiple semiconductor package structures 100′, 100, and 100b. The semiconductor package structure 100′ is similar to the semiconductor package structure 100 of FIG. 1G, and the semiconductor package structure 100 is the same as the semiconductor package structure 100 of FIG. 1G. The semiconductor package structure 100b is similar to the semiconductor package structure 100 of FIG. 1G The difference between the two is the semiconductor package structure 100b further includes a second molding compound 170 on top of the first molding compound 120. The second molding compound 170 covers the pads 130a and the first molding compound 120. Furthermore, the semiconductor package structure 100′ is similar to the semiconductor package structure 100 of FIG. 1G The difference between the two is the semiconductor package structure 100′ is a wafer level package structure that does not perform a singulation process. The semiconductor package structures 100, 100b are chip level package structures.

As seen in FIG. 2, the semiconductor package structures 100, 100b are stacked on the semiconductor package structure 100′. The first solder balls 150 of the semiconductor package structure 100 are correspondingly disposed to the pads 130a of the semiconductor package structure 100′, and the first solder balls 150 of the semiconductor package structure 100b are correspondingly disposed to the pads 130a of the semiconductor package structure 100. Thus, the package thickness can be effectively reduced. Furthermore, after the semiconductor package structures 100, 100b are stacked on the semiconductor package structure 100′, a singulation cutting formation is performed by cutting the semiconductor structure 100′ along line L. This causes the semiconductor package structure 100′ to form a plurality of individual package units (not shown).

To sum up, in the invention, since the metal layer that was formed beforehand is disposed on the first molding compound, thus the semiconductor package structure of the invention has a better heat dissipation effect, and the entire semiconductor structure reliability is increased through the metal layer, to prevent the entire structure from warpage effects. Furthermore, since the method of manufacturing the metal layer has the advantages of simplicity and adaptability for mass production, thus the semiconductor package structure of the invention that adopts the metal layer also effectively reduces production cost.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A method of manufacturing a semiconductor package structure, comprising:
providing a chip, including an active surface and a back surface opposite to each other;
disposing the chip on a carrier, wherein the active surface faces the carrier;
forming a first molding compound on the carrier to cover the chip;
disposing a metal layer on the first molding compound, the metal layer including an upper surface and a lower surface opposite to each other, a plurality of cavities formed on the upper surface and a plurality of protrusions formed on the lower surface and the corresponding to the cavities, wherein the protrusions are embedded into the first molding compound;
patterning the metal layer so as to form a plurality of pads on a portion of the first molding compound, wherein each of the cavities are respectively located on a top surface of each of the pads, and each of the protrusions are respectively located on a bottom surface of each of the pads;
separating the carrier from the first molding compound;
forming a plurality of through holes on the first molding compound so as to expose the protrusions;
forming a redistribution layer on the first molding compound and the active surface of the chip, wherein a portion of the redistribution layer extends from the first molding compound to the active surface of the chip and the through holes, so that the chip is electrically connected to the pads through the portion of the redistribution layer; and
forming a plurality of first solder balls on the redistribution layer, wherein a portion of the first solder balls are correspondingly disposed to the pads.

2. The method of manufacturing a semiconductor package structure as claimed in claim 1, wherein the method of forming the cavities and the protrusions comprises:
providing a metal material layer;
forming a first patterned photoresist layer on a first surface of the metal material layer;
removing a portion of the metal material layer by using the first patterned photoresist layer as a mask to form the cavities on the first surface of the metal material layer;
forming a second patterned photoresist layer on a second surface of the metal material layer; and
removing a portion of the metal material layer by using the second patterned photoresist layer as a mask to form the protrusions on the second surface of the metal material layer.

3. The method of manufacturing the semiconductor package structure as claimed in claim 1, wherein the method of patterning the metal layer comprises:
forming a third patterned photoresist layer on the upper surface of the metal layer; and
removing a portion of the metal layer by using the third photoresist layer as a mask until a portion of the first molding compound is exposed.

4. The method of manufacturing the semiconductor package structure as claimed in claim 1, further comprising:
forming a second solder ball on the top surface of each pad.

5. The method of manufacturing the semiconductor package structure as claimed in claim 1, further comprising:
forming a second molding compound on the first molding compound, wherein the second molding compound covers the pads and the first molding compound.

6. The method of manufacturing the semiconductor package structure as claimed in claim 1, further comprising:
performing a singulation process after forming the first solder balls so as to form a plurality of individual package units.

7. The method of manufacturing the semiconductor package structure as claimed in claim 1, further comprising:
disposing the metal layer on the first molding compound when the first molding compound is in a half-cured state, so that the protrusions are embedded into the first molding compound; and
performing a baking step towards the first molding compound and the metal layer before patterning the metal layer so as to cure the first molding compound.

8. A semiconductor package structure, comprising:
a chip having an active surface and a back surface opposite to each other;
a first molding compound covering the chip and having a plurality of through holes, wherein a bottom surface of the first molding compound and the active surface of the chip are substantially coplanar;
a metal layer disposed on a portion of the first molding compound, and including a plurality of cavities, a plurality of protrusions corresponding to the cavities, and a plurality of pads, wherein each of the cavities are respectively located on a top surface of each of the pads, and each of the protrusions are respectively located on a bottom surface of each of the pads, and the through holes expose the protrusions;
a redistribution layer disposed on the first molding compound and the active surface of the chip, wherein a portion of the redistribution layer extends from the first molding compound to the active surface of the chip and the through holes, so that the chip is electrically connected to the pads through the portion of the redistribution layer; and
a plurality of first solder balls disposed on the redistribution layer, wherein a portion of the first solder balls are correspondingly disposed to the pads.

9. The semiconductor package structure as claimed in claim 8, further comprising a plurality of second solder balls, disposed on the top surface of the pads.

10. The semiconductor package structure as claimed in claim 8, further comprising a second molding compound, disposed on the first molding compound, wherein the second molding compound covers the pads and the first molding compound.
